(19) United States
(12) Patent Application Publication
(10) Pub. No.: US 2012/0286778 A1
(43) Pub. Date: Nov. 15, 2012

(54) METHOD AND DEVICE FOR DETERMINING A MAGNETIC RESONANCE SYSTEM CONTROL SEQUENCE

(76) Inventors: Dirk Diehl, Erlangen (DE); Gabriele Eichfelder, Erfurt (DE); Matthias Gebhardt, Erlangen (DE); Jochen Gierling, Erlangen (DE); Johannes Jahn, Erlangen (DE); Dieter Ritter, Furth (DE)

(21) Appl. No.: 13/413,597

(22) Filed: Mar. 6, 2012

(30) Foreign Application Priority Data
Mar. 7, 2011 (DE) 10 2011 005 174.0

(51) Int. Cl. G01R 33/44

(52) U.S. Cl. 324/307

(57) ABSTRACT

A method for determining a magnetic resonance system control sequence that includes a multichannel pulse with a plurality of individual RF pulses to be transmitted in parallel by a magnetic resonance system via different independent RF transmit channels is provided. Using a predefined target magnetization, a multichannel pulse is determined in an RF pulse optimization method. Pulse shapes of the RF pulses for the different RF transmit channels are each described by a linear combination of trial functions. Coefficients of the linear combinations of trial functions are determined in the RF pulse optimization method.

This application claims the benefit of DE 10 2011 005 174.0, filed on Mar. 7, 2011.

### BACKGROUND

The present embodiments relate to a method and a control sequence determining device for determining a magnetic resonance system control sequence.

In a magnetic resonance system, a body under examination may be exposed to a relatively high main magnetic field, known as the B₀ field, of 3 or 7 teslas, for example, using a main field magnetic system. A magnetic field gradient is additionally applied using a gradient system. Using suitable antenna devices, radiofrequency excitation signals (RF signals) are transmitted via an RF transmission system in order to rotate the nuclear spin of particular atoms resonantly excited by this RF field in a locally resolved manner through a defined flip angle with respect to the lines of force of the main magnetic field. The RF magnetic field transmitted in the form of individual pulses or pulse trains is also known as the B₁ field. This magnetic resonance excitation (MR excitation) by magnetic radiofrequency pulses or, more specifically, the resulting flip angle distribution will hereinafter also be referred to as “nuclear magnetization” or “magnetization.” When the nuclear spin is relaxed, radiofrequency signals (e.g., magnetic resonance signals) are emitted. The magnetic resonance signals are received using suitable receiving antennas and undergo further processing. From the raw data thus acquired, the required image data may be reconstructed. The RF signals for nuclear spin magnetization are mainly transmitted using a body coil. A typical design of a body coil is a birdcage antenna that consists of a plurality of transmitting rods running parallel to the longitudinal axis that are disposed around a patient chamber of the scanner where the patient is positioned for examination. Ends of the antenna rods are capacitively interconnected in a ring. However, local coils placed close to the body are now increasingly being used for transmitting MR excitation signals. The magnetic resonance signals may be received using the local coils, but in many cases, alternatively or additionally using the body coil.

Body coils may be operated in a “homogeneous mode” (e.g., a “CP mode”). For this purpose, a single time-domain RF signal with a defined fixed phase and amplitude ratio is applied to all the components of the transmitting antenna (e.g., all the transmitting rods of a birdcage antenna). With more recent magnetic resonance systems, individual RF signals may be assigned to the individual transmit channels. For this purpose, a multichannel pulse is transmitted that consists of a plurality of radiofrequency pulses that may be transmitted in parallel via the different independent RF transmit channels. Because of the parallel transmission of the individual pulses, such a multichannel pulse train (e.g., a “pTX pulse”) may be used, for example, as an excitation, refocusing and/or inversion pulse. An antenna system with a plurality of independently controllable antenna components (e.g., transmit channels) may also be termed a “transmit array,” irrespective of whether the antenna system is a body coil or an antenna arrangement close to the body.

Such pTX pulses or pulse trains composed thereof may be determined in advance for a particular planned measurement (e.g., the pulse shape and phase, with which transmission is to take place on the individual transmit channels is specified). For this purpose, an optimization method is used to determine the individual RF pulses for the different transmit channels over time as a function of a “transmit k-space gradient trajectory,” which may be specified by a measurement protocol. The “transmit k-space gradient trajectory” (e.g., a gradient trajectory) refers to the locations in k-space that are moved to by adjusting the individual gradients at particular times (e.g., using gradient pulse trains (with appropriate x-, y- and z-gradient pulses) to be transmitted in a coordinated manner, each matching the RF pulse trains). The k-space is the local frequency space, and the gradient trajectory in k-space describes the path on which k-space is traversed in the time domain when an RF pulse or the parallel pulses are transmitted by appropriate switching of the gradient pulses. By adjusting the gradient trajectory in k-space (e.g., by adjusting the appropriate gradient trajectory applied in parallel with the multichannel pulse train), the local frequencies at which particular RF energies are deposited may be determined.

For the planning of the RF pulses, the user specifies a target magnetization (e.g., a required locally resolved flip angle distribution that is used within the target function as a setpoint value). The appropriate RF pulses for the individual channels are then calculated so that the target magnetization is optimally achieved. The basis for this is the Bloch equation

$$\frac{d M}{d t} = γ \cdot M \times B \qquad ( 1 )$$

which describes the magnetization buildup by a magnetization vector M in a magnetic field B. γ is the gyromagnetic ratio of the nucleus to be excited (e.g., for the normally excited hydrogen, γ=42.58 MHz/T).

The pulse shape may be calculated such that a pulse with a particular length is discretized into a number of very short time steps of, for example, 1 to 10 μs duration (e.g., a pulse of 10 to 20 ms contains over 1000 time steps).

For small flip angles, the Bloch equation yields a linear system of equations

A·b=m_{des} (2)

where m_{des} is the vector of the spatially discretized target magnetization, the vector b is the time discretization of the RF pulses, and A is a matrix containing the linear relations resulting from the discretization of the linearized solution of the Bloch equations between the vector m_{des} and the vector b. The solution of this system of equations produces, for each of the time steps, a complex pulse value with a real and an imaginary part, which represent the voltage amplitude and phase of the pulse, for controlling the magnetic resonance system.

The solution may be approximated to as closely as possible in an optimization method using a target function to be minimized corresponding to equation (2). The pulse values for the individual time steps of the pulses are the degrees of freedom or variables of the target function to be optimized. Using a magnitude least squares (MLS) method, the target function may be:

min∥|A·b·−|m_{des}|∥₂² (3)

where the absolute value of a vector is to be understood component-wise. The norm selected is the Euclidean norm (L₂ norm). For the case of large flip angles (e.g., >5°), a similar target function may be formulated, and an optimization (e.g., also an MLS optimization) of the target function may be performed. However, as the system of equations and therefore the target function are nonlinear for large flip angles, this optimization is more complex than for small flip angles. The multichannel pulses are therefore often first calculated in a “low-flip optimization” for a lower target magnetization. The multichannel pulses determined are scaled up to a final target magnetization and if necessary, re-corrected again. Alternatively, the values obtained in the low-flip optimization may also be used as initial values for a subsequent “high-flip optimization” in order to speed up the high-flip optimization.

For the optimization, additional restrictions such as requirements for the maximum RF exposure of a patient, which may be specified by one or more specific absorption rate (SAR) or specific energy dose (SED) limit values, may be taken into account. For this purpose, a suitable energy value representing the energy input or, more specifically, the RF exposure may be taken into account together with the required target magnetization in a target function, on the basis of which the optimization takes place.

For a particular measurement, the different multichannel pulses thus determined or pulse trains comprised thereof, the gradient pulse trains associated with the respective control sequence, and other control requirements are defined in a measurement protocol that is created in advance and called up from a memory (e.g., for a particular measurement). The measurement protocol may be modified locally by the user. During the measurement, the magnetic resonance system is controlled fully automatically on the basis of the measurement protocol, the control device of the magnetic resonance system reading out the commands from the measurement protocol and executing the commands. The pulse shapes calculated are initially generated in digital form in a small-signal generator of the respective transmit channel. The digital signals are converted into an analog signal and amplified by an RF amplifier such that a sufficiently large transmit pulse having the required pulse shape is present. The amplified signal may be injected into the antenna element associated with the respective transmit channel.

Disadvantageously, the optimum pulse shapes developed in accordance with the previously described method as part of planning may exhibit relatively large discontinuities and jumps, which provide that the transmit hardware of the transmit channels is able to convert the pulses into actual signals and inject them into the antenna elements only to a limited extent. For example, the quality of the transfer (e.g., the generation of the pulse on the basis of the theoretically calculated pulse shape and subsequent injection of the pulse into the antenna) also depends on the frequency bandwidth of the pulses. At best, a pulse with a constant frequency may be transferred; at worst, high-frequency random noise may be transferred. For example, if a pulse with a constant frequency is 100% transferred, the transfer rate for a bandwidth of 20 kHz may fall to as low as 10% depending on the system.

The problem of the excessively marked discontinuities within the pulse shape has hitherto not been satisfactorily solved. RF pulses better suited for use on the respective magnetic resonance system have been attempted to be generated by modifying the gradient trajectories so as to achieve smaller step changes in the transmit pulses with respect to absolute value and phase. However, the recourse is to the pulse designer's empirical values.

### SUMMARY AND DESCRIPTION

The present embodiments may obviate one or more of the drawbacks or limitations in the related art. For example, a method and a corresponding control sequence determining device for determining magnetic resonance system control sequences, where better multichannel pulses are generated with less hardware complexity, are provided.

In one embodiment of the method, pulse shapes of the RF pulses for the different RF transmit channels are each described by a linear combination of trial functions. In the RF pulse optimization method, coefficients of the linear combinations are determined as variables to be optimized. A pulse shape of the RF pulse may, for example, be the change in a pulse with respect to an absolute value (e.g., voltage amplitude) and also of a phase over time (e.g., the change in the real and imaginary part), as is mainly also the case in the usual pulse design method.

The approach described is based on the knowledge that the above-described pulse optimization method offers no possibility of limiting the absolute value and phase changes from one time step to the adjacent time step; the pulse values at the discrete time instants are in no way linked. A large number of degrees of freedom in the optimization method is advisable in order to optimally achieve the targets (e.g., the target magnetization and possibly other targets such as minimum RF exposure of the patient).

In order to provide this and nevertheless achieve a “smoother” shape of the pulses to be transmitted, the present embodiments make use of the fact that functions, and therefore also the shape of an RF pulse of a particular time duration, may be represented in the form of a linear combination of suitable trial functions:

$${b}_{c} ( t ) = {\sum }_{k = 1}^{M} {w}_{c}^{k} {a}_{k} ( t ) \qquad ( 4 )$$

where c=1, . . . , C is the index for the respective transmit channel (C is the total number of transmit channels), and b_{c}(t) is accordingly the RF pulse (e.g., a complex pulse value as a function of time t) for the transmit channel c. aₖ(t) are the trial functions, and M is the number of trial functions. w_{c}^{k} are the coefficients of the trial functions (e.g., the weights, with which the individual trial functions aₖ(t) are weighted within the linear combination). By suitable selection of the coefficients w_{c}^{k}, each pulse shape may essentially be represented by such a linear combination provided the trial functions are suitably selected, and the number M of trial functions is sufficiently high.

With the method according to the present embodiments, the same optimization methods (in general, even the same optimization programs or program modules) may be used as in the conventional methods. In the present embodiments, however, the degrees of freedom or variables in the target function are not the independent pulse values in the individual discrete time steps, but instead the coefficients w_{c}^{k}. This provides that there is no need to intervene in the actual solution procedure and, for example, all the other additional optimization tasks such as minimizing the RF exposure of the patient, as well as the boundary conditions, may be taken into account as before. However, since in the method according to the present embodiments, the transmit pulse may be built up as a linear combination of more continuous (e.g., “smoother”) functions, it may automatically be provided that accordingly the entire pulse shape assumes a continuous, “smooth” pattern. Such pulses are consequently simpler for the hardware components of the magnetic resonance system to generate with a high transfer rate and inject into the antenna system, thereby significantly improving the excitation quality.

In addition, with the method according to the present embodiments, the number of variables to be optimized may be reduced compared to the conventional method described in the introduction, which enables the pulses to be calculated faster. However, with the method according to the present embodiments, the target magnetization may be achieved virtually equally as well as using the conventional method.

The method according to the present embodiments is suitable not only for “low-flip optimization” but also for “high-flip optimization.” In addition, the multichannel pulses may first be calculated in a “low-flip optimization,” and the coefficients thereby obtained may be used as initial values as part of a subsequent “high-flip optimization.” The multichannel pulses obtained from the “low-flip optimization” may be scaled up to a final target magnetization. If, for example, the calculation is performed in the low-flip range for a flip angle of maximum α=5°, and the actual magnetization is to take place with a flip angle α of max 90°, the amplitude values of the RF pulses may be multiplied by a factor of 18 according to the ratio of the flip angles. The errors occurring may be determined, for example, as part of a (Bloch) simulation and corrected.

A control sequence determining device according to one embodiment includes an input interface for acquiring a target magnetization. The control sequence determining device also includes an RF pulse optimization unit in order to calculate a multichannel pulse on the basis of a specified target magnetization in an RF pulse optimization method. The control sequence determining device includes a control sequence output interface in order to transfer the control sequence for controlling the magnetic resonance system for data acquisition to a control device or to store the control sequence in a memory for that purpose. The control sequence determining device is implemented such that the pulse shapes of the individual RF pulses for the various RF transmit channels are each described by a linear combination of trial functions, and coefficients of the linear combinations are determined as part of the RF pulse optimization method.

In one embodiment of a method for operating a magnetic resonance system, a control sequence is determined according to the above-described process, and the magnetic resonance system is operated using the control sequence. Accordingly, the magnetic resonance system of the type referred to in the introduction has an above-described control sequence determining device.

Parts of the control sequence determining device may be implemented in the form of software components. This applies, for example, to the RF pulse optimization unit. The input interface may be, for example, a user interface for manually entering a target magnetization (e.g., a graphical user interface). The user interface may also be an interface for selecting or retrieving data (e.g., information concerning the trial functions to be used) from a data memory disposed inside the control sequence determining device or connected thereto via a network (e.g., using the user interface). The control sequence output interface may, for example, be an interface that communicates the control sequence to a magnetic resonance controller in order to directly control the measurement thereby. The control sequence output interface may also be an interface that transmits the data via a network and/or stores the data in a memory for later use. Some of these interfaces may be realized in software and/or may use hardware interfaces of an existing computer.

The present embodiments also include a computer program that may be loaded directly into the memory of the control sequence determining device, with program code sections for executing all the steps of the method according to the present embodiments when the program is run in the control sequence determining device. A software implementation of this kind has the advantage that, by suitably implementing the program, existing equipment used for determining control sequences (e.g., suitable computers in computing centers of magnetic resonance system manufacturers) may also be modified in order to determine control sequences that are quicker to calculate and may be run more easily and with a higher transfer quality on the MR machine.

The claims of one category may also be further developed analogously to the dependent claims of another claim category.

For the method according to the present embodiments, a wide variety of trial functions may be used. Continuous functions may be used as trial functions.

The trial functions are selected such that the trial functions are mutually linearly independent and therefore constitute an orthogonal system. A larger space may be spanned with orthogonal functions.

In one embodiment, development functions of the finite Fourier series

1,cos(kωt),sin(kωt), mit k=1, 2, 3, . . . , M (5)

are selected as trial functions over the interval [0,T]. The parameter ω=2π/T is defined such that the functions cos(ωt) and sin(ωt) execute precisely a full wave over the duration T of a pulse. The highest frequency present in the pulse may be defined by the number M of Fourier trial functions used. The frequency bandwidth of the pulse generated may therefore be very well controlled using these functions. The larger the number M of Fourier trial functions, the larger the quantity of RF pulses that may be generated. The use of higher frequency sine and cosine functions is at the expense of the smoothness of the functions composed thereof. The Fourier series functions are orthogonal.

Local sine functions may be selected as trial functions. The local sine functions are of similar structure to the development functions of the Fourier series. However, unlike the carriers of the Fourier series, these functions do not have temporal effect everywhere, but only locally. They may be formally represented over [0,T] with ω=2π/T by

$${f}_{n m} ( t ) = \{ \begin{matrix}sin ( ω n t ) & for \frac{mT}{n} \leq t \leq \frac{( m + 1 ) T}{n} \\ 0 & otherwise\end{matrix} \qquad ( 6 )$$

with n=1, 2, . . . , M and m=0, 1, 2, . . . , n−1. As in the case of the Fourier series, the constant 1 is added as a function. These local sine functions are also orthogonal. The local sine functions have the advantage, for example, of resolution both in the frequency and in the time domain.

Other functions that may be used are, for example, polynomials (e.g., orthogonal polynomials), such as the Chebyshev polynomials, Legendre polynomials, Hermite polynomials or Laguerre polynomials, which may be represented recursively in each case. All these functions may be used as function bases for pulse design using trial functions.

Simpler functions may also be used as a trial function, the monomials constituting the simplest form of a polynomial base. The functions

1,x,x²,x³,x⁴,x⁵, (7)

may be used as trial functions within this framework. They may be limited to suitable intervals.

Discrete wavelets may be used as trial function types. One advantage of wavelets is again the possibility of resolution both in the frequency and in the time domain.

Another parameter that may be specified for the optimization method is the number of trial functions that are used within the framework of the linear combination. The optimum number of trial functions is dependent on the number of coils used and the number of resolvable time steps for time discretization. In one embodiment, considerably fewer trial functions are used than resolvable time steps selected. The number of trial functions may be about one third to two thirds of the time discretization steps (e.g., approximately half the time discretization steps).

When selecting development functions of the Fourier series as trial functions, the number of trial functions may be selected such that a pulse frequency bandwidth is below a specified maximum value. In this way, as will be further explained below, the transfer rate may be kept as high as possible.

In the context of the RF pulse optimization method, all the other boundary conditions may be specified as for the existing optimization method. For example, a gradient trajectory, a B₀ map (e.g., a map representing the B₀ field homogeneity determined in a test measurement in a particular region to be excited), as well as corresponding B₁ maps representing the B₁ field strength in the region to be excited for the individual transmit channels, may be used as input data for the optimization method.

### BRIEF DESCRIPTION OF THE DRAWINGS

FIG. 1 illustrates one embodiment of a magnetic resonance system;

FIG. 2 illustrates a birdcage antenna with eight antenna rods that are supplied via separate transmit channels with pulses of a multichannel pulse that are to be transmitted in parallel;

FIG. 3 shows a frequency spectrum of an RF pulse with a Gaussian curve that shows the transferable amplitude component as a function of the frequency bandwidth of the RF pulse;

FIG. 4 shows an example of a voltage amplitude characteristic of an RF pulse generated using a conventional method;

FIG. 5 shows, for comparison with FIG. 3, a voltage amplitude characteristic of an RF pulse generated using one embodiment of a method for determining a magnetic resonance system control sequence; and

FIG. 6 shows various magnetic resonance images of an oil phantom acquired with RF pulses generated using different numbers of trial functions, in comparison with a magnetic resonance image of the same oil phantom generated using an RF pulse produced in a conventional manner (far left).

### DETAILED DESCRIPTION OF THE DRAWINGS

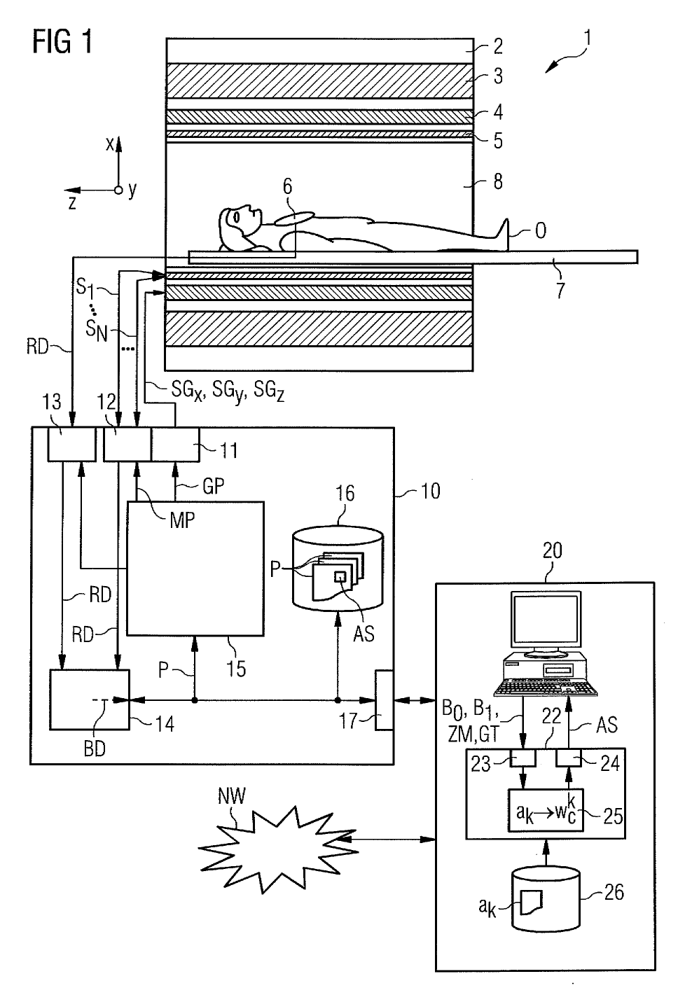

FIG. 1 shows a highly schematic representation of one embodiment of a magnetic resonance system 1. The magnetic resonance system 1 includes a magnetic resonance scanner 2 incorporating an examination chamber 8 or patient tunnel 8. A table 7 may be moved into the patient tunnel 8 so that during an examination, a patient O or proband located thereon may be placed at a particular position inside the magnetic resonance scanner 2 relative to the magnetic system and RF system disposed therein or may also be moved between different positions during a measurement.

The magnetic resonance scanner 2 includes a main field magnet 3, a gradient system 4 with magnetic field gradient coils in order to apply any magnetic field gradients in the x-, y- and z-direction, and an RF body coil 5. The magnetic resonance signals induced in the examination subject O may be received via the body coil 5, with which the RF signals for inducing the magnetic resonance signals may also be transmitted. However, the magnetic resonance signals may also be received using local coils 6 placed, for example, on or under the patient O. These components are basically known and are therefore only shown in a highly schematic manner in FIG. 1.

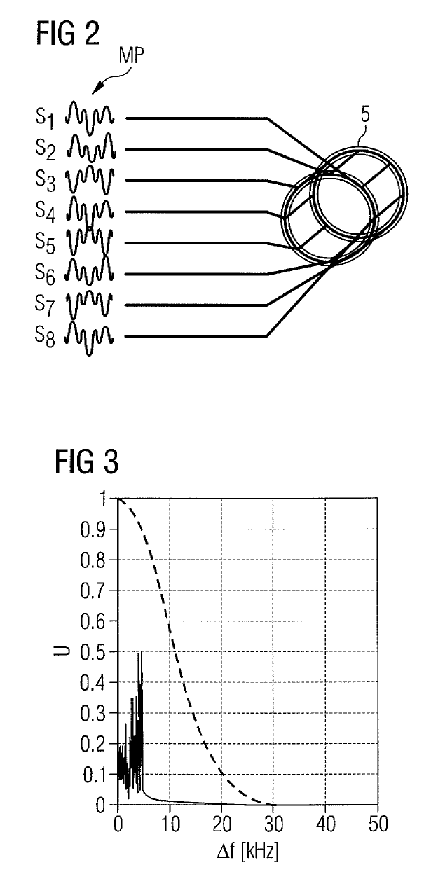

The RF body coil 5 is, for example, designed in the form of a birdcage antenna and has a number N of individual antenna rods that run parallel to the patient tunnel 8 and are disposed circumferentially around the patient tunnel 8 in an evenly distributed manner. At ends of the individual antenna rods, the individual antenna rods are capacitively connected in a ring. Such a construction is again shown in FIG. 2.

The individual antenna rods each form part of a transmit channel S₁, . . . , S_{N} separately controllable by a control device 10 (see FIG. 1). The individual RF pulses that are injected in parallel into the antenna 5 on the different transmit channels S₁, . . . , S_{N} and are transmitted by the antenna and are then heterodyned inside the antenna 5 to produce an RF pulse with a particular spatial magnetic field distribution, together form a multichannel pulse MP. A plurality of the multichannel pulses MP may be determined successively as a complete multichannel pulse train and transmitted in a corresponding sequence. Some multichannel pulses MP of the plurality are used for excitation for data acquisition and others again for refocusing, fat saturation, etc.

The control device 10 may be a control computer that may include a plurality of individual computers (e.g., physically separated and interconnected by suitable cables or the like). Via a terminal interface 17, the control device 10 may be connected to a terminal 20, via which an operator may control the entire system 1. The terminal 20, for example, is equipped as a computer with keyboard, one or more monitor screens, and other input devices such as a mouse or the like, so that a graphical user interface is available to the operator.

The control device 10 includes, for example, a gradient control unit 11 that may include a plurality of sub-components. The gradient control unit 11 is used to connect the individual gradient coils to gradient control signals SGₓ, SG_{y}, SG_{z}. The gradient control signals SGₓ, SG_{y}, SG_{z} are gradient pulses that, during a measurement, are set at precisely provided positions in time and with a precisely specified time characteristic.

The control device 10 also has an RF transmit/receive unit 12. The RF transmit/receive unit 12 includes a plurality of sub-components in order to apply RF pulses separately and in parallel to the individual transmit channels S₁, . . . S_{N} (e.g., to the individual controllable antenna rods of the body coil). Although magnetic resonance signals may also be received via the transmit/receive unit 12, this may be performed using the local coils 6. Raw data RD received using the local coils 6 is read and processed by an RF receive unit 13. The magnetic resonance signals received therefrom or from the body coil using the RF transmit/receive unit 12 are transferred as raw data RD to a reconstruction unit 14 that reconstructs image data BD from the raw data RD and stores the image data BD in a memory 16 and/or transfers the image data BD via an interface 17 to the terminal 20 so that the operator may view the image data BD. The image data BD may also be stored and/or displayed and analyzed at other locations via a network NW.

The gradient control unit 11, the RF transmit/receive unit 12 and the receive unit 13 for the local coils 6 are each controlled in a coordinated manner by a measurement control unit 15. By appropriate commands, the measurement control unit 15 provides that a required gradient pulse train GP is transmitted by suitable gradient pulse control signals SGₓ, SG_{y}, SG_{z}, and controls, in parallel, the RF transmit/receive unit 12, such that a multichannel pulse train with a plurality of consecutive multichannel pulses MP is transmitted (e.g., the appropriate RF pulses are applied to the individual transmitting rods of the body coil 5 in parallel on the individual transmit channels S₁, . . . S_{N}). In addition, the magnetic resonance signals on the local coils 6 and any signals on the body coil 5 are read out and further processed by the RF receive unit 13 and the RF transmit/receive unit 12, respectively, at the appropriate instant. The measurement control unit 15 specifies the corresponding signals (e.g., the multichannel pulses MP or the multichannel pulse train) to the RF transmit/receive unit 12 and the gradient pulse train GP to the gradient control unit 11, according to a predefined control protocol P. Stored in the control protocol P is all the control data that is to be adjusted during a measurement.

A large number of control protocols P for various measurements may be stored in a memory 16. The control protocols P may be selected and, if necessary, varied by the operator via the terminal 20 in order to have available for the current measurement, an appropriate control protocol P, with which the measurement control unit 15 may operate. Otherwise, the operator may also retrieve control protocols P, for example, from a manufacturer of the magnetic resonance system 1 via a network NW. If necessary, the operator may modify the control protocols P and use the control protocols P.

The basic sequence of such a magnetic resonance measurement and the control components mentioned are known and thus are not discussed in further detail. Such a magnetic resonance scanner 2 and the associated control device 10 may also have a large number of further components that will likewise not be explained in further detail.

The magnetic resonance scanner 2 may also be of different design (e.g., having a patient tunnel open to a side; the RF body coil is not constructed as a birdcage antenna). The magnetic resonance scanner 2 has a plurality of separately controllable transmit channels S₁, . . . , S_{N} and, accordingly, in the control device 10, a corresponding number of channel controllers is provided by the RF transmit/receive device in order to be able to control the individual transmit channels S₁, . . . , S_{N} separately.

FIG. 1 schematically illustrates a control sequence determining device 22 that is used for determining a magnetic resonance system control sequence AS. The magnetic resonance system control sequence AS contains, among other things, for a particular measurement, a predefined multichannel pulse train MP for controlling the individual transmit channels S₁, . . . , S_{N}. The magnetic resonance system control sequence AS is, for example, created as part of the measurement protocol P.

The control sequence determining device 22 is shown in FIG. 1 as part of the terminal 20 and may be implemented in the form of software components on the computer of the terminal 20. However, the control sequence determining device 22 may also be part of the control device 10 or be implemented on a separate computing system, and the finished control sequences AS are communicated to the magnetic resonance system 1 via a network NW (e.g., also within the framework of a complete control protocol P).

The control sequence determining device 22 has, for example, an input interface 23. Via the input interface 23, the control sequence determining device 22 receives a target magnetization ZM that specifies a flip angle distribution for the desired measurement. A gradient trajectory GT may also be specified. The target magnetization ZM and the gradient trajectory GT may be predefined by an expert, for example, with sufficient training to develop control protocols for particular measurements. In addition, a B₀ map and B₁ maps for the various transmit channels, which were acquired in advance with the patient O in the scanner 2 as part of adjustment measurements, may be taken over, for example, by the control device 10 as input values for determining the suitable multichannel pulses.

The data thus obtained is then transferred to an RF pulse optimization unit 25 that automatically creates a particular control sequence AS with an optimum multichannel pulse MP for achieving the required target magnetization ZM (or more specifically a complete multichannel pulse train with a plurality of multichannel pulses). This takes place, as will be explained below, using trial functions aₖ that may be stored, for example, in a memory 26 that may be accessed by the RF pulse optimization unit 25.

The optimum RF pulses or pulse trains determined may be output via a control sequence output interface 24 and transferred, for example, as part of a control protocol P that also contains further specifications (e.g., parameters for reconstructing the images from the raw data, etc.) to the control device 10. The control device 10 controls the magnetic resonance system 1 accordingly for the measurement.

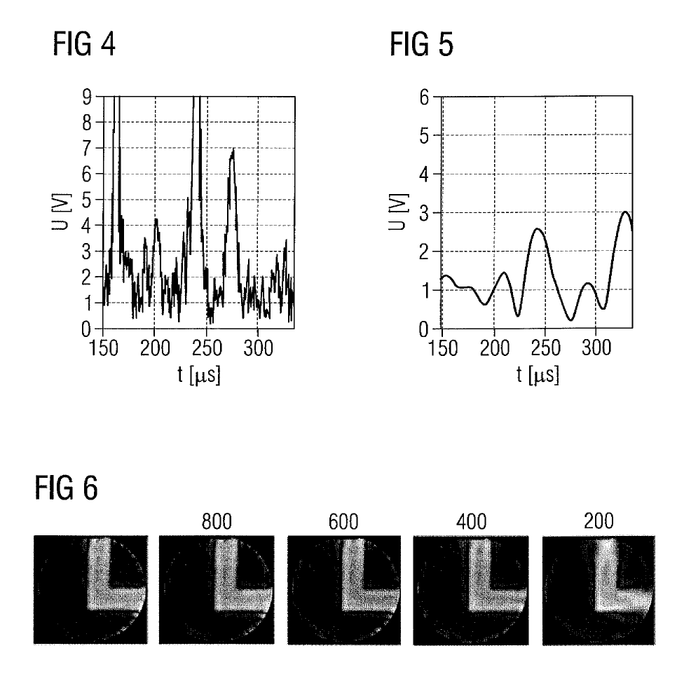

The existing pulse calculation methods result in the RF pulses to be transmitted being very discontinuous. This may be seen from the example in FIG. 4 that shows the variation in the voltage amplitude U (in volts) over time t (in μs) of a section of a typical RF pulse that was determined using a conventional method. The discontinuities are attributable to the fact that large differences between consecutive time steps may occur due to the time discretization and independent calculation of the respective amplitude values (e.g., also of the phases (i.e., the complex pulse values)). With these large discontinuities, the pulses determined as theoretically optimum cannot be generated and transmitted via the antenna system by the hardware of the transmit channels in the corresponding shape. The actually transmitted RF pulses do not correspond to the theoretically determined optimum pulses, and the target magnetization is consequently not as well achieved as should be the case on the basis of the RF pulses determined in advance during planning.

Another problem is that these discontinuities result in a considerable widening of the frequency bandwidth of the transmitted pulses. This reduces, as explained above, the transfer quality. This may be seen from FIG. 3, for example, which shows the voltage amplitude U (normalized to a maximum amplitude of 1) versus the frequency bandwidth f in kHz. The Gaussian curve (dashed curve) represents the possible transfer rate. At a frequency bandwidth of 0, which corresponds to an RF pulse with a constant frequency (e.g., the Larmor frequency required for excitation), transfer takes place with an amplitude of 1 (e.g., 100%). At 20 kHz, however, the transfer rate is only 10%. FIG. 3 also shows the spectral analysis of an RF pulse. In order to calculate the transfer coefficient, which represents the quality of transfer of this RF pulse (e.g., generation and injection of the RF pulse into the antenna system), the area below the Gaussian weighted spectral curve may first be calculated. The resulting value may be divided by the area below the spectral curve to obtain the transfer coefficient. FIG. 3 shows that the more and higher values the spectral curve of the pulse has as near as possible to the origin, the better the transfer coefficient (e.g., the quality of the transfer). Also, for this reason, it is advantageous to limit the bandwidth of the RF pulse as much as possible, provided this is possible without great loss in achieving the target magnetization.

In order to obtain a “smoother” RF pulse with smaller frequency bandwidth, the RF pulse optimization unit 25 operates such that the pulse shape is represented by a linear combination of weighted trial functions, as explained above with reference to equation (4).

As defined by equation (4), the time discretizations b₁, b₂, b₃, b_{c} of the RF pulses b_{c}(t) of the individual transmit channels c (with c=1, . . . , C) may be combined for this purpose to produce the following vector:

$$b = ( \begin{matrix}{b}_{1} \\ {b}_{2} \\ {b}_{3} \\ ⋮ \\ {b}_{c}\end{matrix} ) \qquad ( 8 )$$

In other words, the vector b contains, as individual elements for each transmit channel c, the time-discretized values of the pulse b_{c}(t). Therefore, if the individual pulses b_{c}(t) are each discretized into a thousand time steps and there are a total of eight separate transmit channels, the vector contains, in accordance with equation (9), a total of 8000 elements that are each successively grouped according to transmit channels. The individual values for the discrete time steps are consecutive in each group.

If this vector is inserted into the system of equations according to equation (2), the following vector equation is obtained:

$${m}_{des} = A ( \begin{matrix}{\sum }_{k = 1}^{M} {w}_{1}^{k} {a}_{k} \\ {\sum }_{k = 1}^{M} {w}_{2}^{k} {a}_{k} \\ {\sum }_{k = 1}^{M} {w}_{3}^{k} {a}_{k} \\ ⋮ \\ {\sum }_{k = 1}^{M} {w}_{C}^{k} {a}_{k}\end{matrix} ) \qquad ( 9 )$$

where the vectors a₁, a₂, . . . , a_{M} in the sums are each the parts of the trial functions a₁(t), a₂(t), . . . , aₘ(t) that are time-discretized according to the pulses. In this system of equations, the weights w_{c}^{k} of the trial functions appear as single unknowns. Using the notation w_{c}=(w_{c}¹, w_{c}², . . . , w_{c}^{M})^{T} (the superscript T indicates that the vector is transposed) and A′=(a₁, a₂, . . . , a_{M}), equation (9) may be re-written in the form

$${m}_{des} = A ( \begin{matrix}{A}^{′} {w}_{1} \\ {A}^{′} {w}_{2} \\ {A}^{′} {w}_{3} \\ ⋮ \\ {A}^{′} {w}_{C}\end{matrix} ) \qquad ( 10 )$$

With the unknown vector w=(w₁^{T}, w₂^{T}, . . . , w_{c}^{T})^{T} and the matrix

$$B = A ( \begin{matrix}{A}^{′} & & & & \\ & … & & & \\ & & … & & \\ & & & … & \\ & & & & {A}^{′}\end{matrix} ) \qquad ( 11 )$$

the linear system of equations

m_{des}=Bw (12)

may be formed therefrom.

Similarly to the system of equations according to equation (2), this system of equations may be solved as part of a usual optimization, where the target function may be built up in different ways. The specified magnetization m_{des} may be a real-valued vector, whereas B and w are complex-valued vectors. If only the absolute values of the magnetization are to be optimized, the associated optimization problem or, more specifically, the target function may be, for example,

$${min}_{w ∈ {C}^{NC}} {‖ \vert Bw \vert - \vert {m}_{des} \vert ‖}_{2}^{2} \qquad ( 13 )$$

If the absolute value and phase of the magnetization are to be optimized, the optimization problem or, more specifically, the target function may be, for example,

$${min}_{w ∈ {C}^{NC}} {‖ Bw - {m}_{des} ‖}_{2}^{2} \qquad ( 14 )$$

The above-described target functions (e.g., optimization tasks) precisely correspond to the optimization problems that also arise in the conventional methods without trial functions. As already explained above, the target functions may therefore advantageously be approached using precisely the same optimization methods.

FIG. 5 shows, by way of comparison with FIG. 4, an extract from the voltage characteristic of an RF pulse optimized using the method according to the present embodiments. The pulse is generated for the same target magnetization as the pulse from FIG. 4. Here, the development functions of the discontinuous Fourier series:

a₁(t)=1,a₂(t)=cos(wt),a₃(t)=sin(wt),a₄(t)=cos(2wt),a₅(t)=sin(2wt), (15)

have been used as trial functions (cf. equation (6)).

If these functions are inserted into equation (4), the linear combination

$${b}_{c} ( t ) = {w}_{c}^{1} + {\sum }_{{k = 2}_{k even}}^{m} {w}_{c}^{k} cos ( \frac{k}{2} wt ) + {\sum }_{{k = 3}_{k odd}}^{m} {w}_{c}^{k} sin ( \frac{k - 1}{2} wt ) \qquad ( 16 )$$

is obtained for the mathematical description of the pulse shape. As shown in FIG. 5 in comparison with FIG. 4, an RF pulse constructed in this way is considerably smoother and may therefore be generated more simply and also transmitted with higher quality by the transmit system hardware. The number of trial functions used may be selected such that the approximation to the ideal pulse shape is not significantly constrained, while the frequency bandwidth does not become too large. The number of trial functions has been found to be one that corresponds to between one third and two thirds of the time discretization steps of the pulse (e.g., approximately half the number of time discretization steps).

FIG. 6 shows a comparison of different magnetic resonance images of the same oil phantom acquired using different RF pulses generated using different numbers of trial functions in the manner of the present embodiments. The same type of trial functions was used in each case (e.g., the above-described development functions of the Fourier series). The number of trial functions is indicated above the individual images in each case. Illustrated for comparison on the far left is an image acquired using a conventionally generated RF pulse. FIG. 6 shows that for 800, 600 and 400 trial functions, the required target magnetization is very well achieved in each case, and there are no discernable differences with respect to the pulses generated in the conventional manner. However, pulse calculation is considerably quicker due to the limited number of variables in the optimization method.

The above-described detailed methods and setups are examples, and the basic principle may also be varied within wide limits by the average person skilled in the art without departing from the scope of invention in so far as is specified by the claims. Thus, even if the detailed example has been explained above for a small flip angle scenario, the method according to the present embodiments may also be used for larger flip angles, even though the target function is nonlinear in the case of high-flip optimization. In the usual optimization methods, the Jacobi matrix, which represents the change in the target function relative to the pulse vector inputs (e.g., representing the first derivative of the target function), is used to solve the nonlinear system of equations. Within the framework of use of the present embodiments (e.g., in the case of such an optimization method), both the target function and the Jacobi matrix may advantageously be modified such that the weights of the trial functions occur as variables. Using a suitable linear transformation, the conventional Jacobi matrix may be readily transformed into a modified Jacobi matrix, in which the trial functions are contained as variables. The use of the indefinite article “a” or “an” does not exclude the possibility that more than one of the features in question may be present. The use of the terms “unit” and “module” does not exclude the possibility that “module” consists of a plurality of components that may also possibly be spatially distributed.

The instructions for implementing the processes, methods and/or techniques discussed herein are provided on computer-readable storage media or memories, such as a cache, buffer, RAM, removable media, hard drive or other computer readable storage media. Computer readable storage media include various types of volatile and nonvolatile storage media. The functions, acts or tasks illustrated in the figures or described herein are executed in response to one or more sets of instructions stored in or on computer readable storage media. The functions, acts or tasks are independent of the particular type of instructions set, storage media, processor or processing strategy and may be performed by software, hardware, integrated circuits, firmware, micro code and the like, operating alone or in combination.

While the present invention has been described above by reference to various embodiments, it should be understood that many changes and modifications can be made to the described embodiments. It is therefore intended that the foregoing description be regarded as illustrative rather than limiting, and that it be understood that all equivalents and/or combinations of embodiments are intended to be included in this description.

1. A method for determining a magnetic resonance system control sequence comprising a multichannel pulse with a plurality of individual RF pulses to be transmitted in parallel by a magnetic resonance system via different independent RF transmit channels, the method comprising:
determining the multichannel pulse on the basis of a predefined target magnetization in an RF pulse optimization method, wherein pulse shapes of the RF pulses for the different independent RF transmit channels are each described by a linear combination of trial functions; and
determining coefficients of the linear combinations in the RF pulse optimization method.

2. The method as claimed in claim 1, wherein the trial functions are mutually linearly independent.

3. The method as claimed in claim 1, wherein the trial functions are continuous functions.

4. The method as claimed in claim 1, wherein Fourier series functions are selected as the trial functions.

5. The method as claimed in claim 1, wherein the trial functions comprise local sine functions, Chebyshev polynomials, Legendre polynomials, Hermite polynomials, Laguerre polynomials, monomials, discrete wavelets, or a combination thereof.

6. The method as claimed in claim 1, wherein the number of trial functions used is selected such that a pulse frequency bandwidth is below a specified maximum value.

7. The method as claimed in claim 1, wherein a gradient trajectory, a current B₀ map, and for each of the different independent RF transmit channels, a current B₁ map are specified as input data for the RF pulse optimization method.

8. The method as claimed in claim 2, wherein the trial functions are continuous functions.

9. The method as claimed in claim 2, wherein Fourier series functions are selected as the trial functions.

10. The method as claimed in claim 3, wherein Fourier series functions are selected as the trial functions.

11. The method as claimed in claim 2, wherein the trial functions comprise local sine functions, Chebyshev polynomials, Legendre polynomials, Hermite polynomials, Laguerre polynomials, monomials, discrete wavelets, or a combination thereof.

12. The method as claimed in claim 4, wherein the trial functions comprise local sine functions, Chebyshev polynomials, Legendre polynomials, Hermite polynomials, Laguerre polynomials, monomials, discrete wavelets, or a combination thereof.

13. The method as claimed in claim 3, wherein the number of trial functions used is selected such that a pulse frequency bandwidth is below a specified maximum value.

14. The method as claimed in claim 5, wherein the number of trial functions used is selected such that a pulse frequency bandwidth is below a specified maximum value.

15. The method as claimed in claim 4, wherein the number of trial functions used is selected such that a pulse frequency bandwidth is below a specified maximum value.

16. The method as claimed in claim 6, wherein a gradient trajectory, a current B₀ map, and for each of the different independent RF transmit channels, a current B₁ map are specified as input data for the RF pulse optimization method.

17. A method for operating a magnetic resonance system having a plurality of independent RF transmit channels, the method comprising:
determining a magnetic resonance system control sequence comprising a multichannel pulse with a plurality of individual RF pulses to be transmitted in parallel by the magnetic resonance system via the plurality of independent RF transmit channels,
wherein the determining comprises:
determining the multichannel pulse on the basis of a predefined target magnetization in an RF pulse optimization method, wherein pulse shapes of the RF pulses for the different independent RF transmit channels are each described by a linear combination of trial functions; and
determining coefficients of the linear combinations in the RF pulse optimization method; and
operating the magnetic resonance system using the magnetic resonance system control sequence.

18. A control sequence determining device for determining a magnetic resonance system control sequence comprising a multichannel pulse with a plurality of individual RF pulses to be transmitted in parallel by a magnetic resonance system via different independent RF transmit channels, the control sequence determining device comprising:
an input interface operable to determine a target magnetization;
an RF pulse optimization unit operable to determine the multichannel pulse on the basis of the target magnetization in a RF pulse optimization method; and
a control sequence output interface,
wherein the control sequence determining device is implemented such that pulse shapes of the individual RF pulses for the different RF transmit channels are each described by a linear combination of trial functions, and coefficients of the linear combinations of trial functions are determined in the RF pulse optimization method.

19. A magnetic resonance system with a plurality of independent RF transmit channels, the magnetic resonance system comprising:
a gradient system;
a control device configured to transmit a multichannel pulse comprising a plurality of parallel individual RF pulses via the plurality of independent RF transmit channels in order to carry out a required measurement on the basis of a specified control sequence; and
a control sequence determining device for determining a magnetic resonance system control sequence comprising the multichannel pulse, the control sequence determining device comprising:
an input interface operable to acquire a target magnetization;
an RF pulse optimization unit operable to determine the multichannel pulse on the basis of the target magnetization in a RF pulse optimization method; and
a control sequence output interface,
wherein the control sequence determining device is implemented such that pulse shapes of the individual RF pulses for the different RF transmit channels are each described by a linear combination of trial functions, and coefficients of the linear combinations of trial functions are determined in the RF pulse optimization method, and
wherein the control sequence determining device is operable to transfer the magnetic resonance system control sequence to the control device.

20. In a non-transitory computer-readable storage medium that stores instructions executable by a control sequence determining device to determine a magnetic resonance system control sequence comprising a multichannel pulse with a plurality of individual RF pulses to be transmitted in parallel by a magnetic resonance system via different independent RF transmit channels, the instructions comprising:
determining the multichannel pulse on the basis of a predefined target magnetization in an RF pulse optimization method, wherein pulse shapes of the RF pulses for the different independent RF transmit channels are each described by a linear combination of trial functions; and
determining coefficients of the linear combinations in the RF pulse optimization method.
